(19) United States
(12) Patent Application Publication
(10) Pub. No.: US 2005/0269680 A1
(43) Pub. Date: Dec. 8, 2005

(54) System-in-package (SIP) structure and fabrication thereof

(76) Inventor: Min-Chih Hsuan, Hsinchu (TW)

Correspondence Address: J C PATENTS, INC., 4 VENTURE, SUITE 250, IRVINE, CA, 92618, US

(21) Appl. No.: 10/864,116

(22) Filed: Jun. 8, 2004

(51) Int. Cl. H01L 23/48; H01L 21/58

(52) U.S. Cl. 257/686; 438/458; 438/613; 438/109; 257/737

(57) ABSTRACT

A system-in-package (SIP) structure is described, including stacked circuit/insulator composite layers, bumps and a cover plate. Each circuit/insulator composite layer is lifted off from a semiconductor-on-insulator (SOI) substrate, including the insulator of the SOI substrate and a circuit layer based on the semiconductor of the SOI substrate. The circuit layer of a circuit/insulator composite layer is electrically coupled with the circuit layer of the underlying circuit/insulator composite layer. The bumps are disposed on the lower surface of the bottom circuit/insulator composite layer, electrically coupled with the circuit layer of the bottom circuit/insulator composite layer. The cover plate is disposed on the top circuit/insulator composite layer.

### BACKGROUND OF THE INVENTION

1. Field of the Invention

The present invention relates to a semiconductor apparatus. More particularly, the present invention relates to a system-in-package (SIP) structure and a method for fabricating the same.

2. Description of the Related Art

SIP technique is very useful in compactification of electronic system, and reducing the thickness of SIP is very important in related fields. In the prior art, an SIP structure is formed with wire bonding or 3D solder-ball stacking.

FIG. 1 illustrates a conventional SIP structure that is usually called stacked CSP (chip-scale package). Referring to FIG. 1, the stacked CSP includes a first chip 100, a second chip 110 and a third chip 120 that are sequentially stacked on a carrier substrate 130 interposed by underfill 135. Each chip (100, 110 or 120) is electrically connected to the circuit of the carrier substrate 130 using bumps (not shown) and bonding wires 140, so that the size of the three chips 100-120 has to be reduced gradually. The circuit of the carrier substrate 130 is connected to ball pads 150 on the bottom surface of the carrier substrate 130, and solder balls 160 are formed on the ball pads 150.

FIG. 2 illustrates another conventional SIP structure that is Sharp's 3D MCP (multi-chip package) for memory application. The 3D MCP consists of several stack units 200 that are stacked vertically. Each stack unit 200 includes a carrier substrate 210, two memory chips 220 sealed in a sealing resin 230, lead wires and bonding wires 240 electrically connecting the memory chips 220 and the circuit in the carrier substrate 210, ball pads 250, through plugs 260 and solder balls 270. Each bonding wire 240 is electrically connected to the corresponding chip 220 via a bump (not shown). Each through plug 260 is electrically connected with the circuit in the carrier substrate 210, and is connected between two ball pads 250 respectively on the upper side and the lower side of the carrier substrate 210. The solder balls 270 are disposed on the ball pads 250 on the lower side of the carrier substrate 210 to contact with the ball pads 250 on the upper side of the carrier substrate 210 of the underlying stack unit 200. As compared with the stacked CSP, Sharp's 3D MCP does not require each chip to be different in size, but does require more carrier substrates.

Since the thickness of a chip is the same as that of a wafer, the thickness of the conventional SIP structures cannot be easily reduced. Moreover, the conventional carrier substrate is usually a printed circuit board (PBC) and the bump material for wire bonding is mostly gold, so that the costs of the conventional SIP structures are higher. Furthermore, the conventional carrier substrate, which is usually a printed circuit board (PBC), makes the conventional SIP structures difficult to thin down.

### SUMMARY OF THE INVENTION

In view of the foregoing, an object of this invention is to provide a SIP structure that has a reduced thickness.

Another object of this invention is to provide a SIP structure that neither requires each stacked unit to be different in size nor needs any conventional carrier substrate, and uses less bumps.

Still another object of this invention is to provide a SIP structure that allows a thinner carrier substrate to be used.

This invention also provides a method for fabricating the SIP structure of this invention.

The SIP structure of this invention includes stacked circuit/insulator composite layers, bumps and a cover plate. Each circuit/insulator composite layer is lifted off from a semiconductor-on-insulator (SOI) substrate, including the insulator of the SOI substrate and a circuit layer based on the semiconductor of the SOI substrate. The circuit layer of a composite layer is electrically coupled with the circuit layer of the underlying composite layer. The bumps are disposed on the lower surface of the bottom composite layer, electrically coupled with the circuit layer of the bottom composite layer. The cover plate is disposed on the top composite layer, serving as a carrier substrate.

In an embodiment of this invention, the insulator of each composite layer faces down, the bumps are disposed on the lower surface of the insulator of the bottom composite layer, and the cover plate on the circuit layer of the top composite layer. In another embodiment, however, it is the circuit layer of each composite layer that faces down, while the bumps are disposed on the circuit layer of the bottom composite layer and the cover plate on the insulator of the top composite layer.

The method for fabricating a SIP structure of this invention includes the following steps. In step (a), multiple semiconductor-on-insulator (SOI) substrates, each of which includes an insulator and a circuit layer on the insulator, are provided. In step (b), the insulator and the circuit layer of each SOI substrate are lifted off to be multiple circuit/insulator composite layers. In step (c), the composite layers are vertically stacked with the circuit layer of a composite layer being coupled with the circuit layer of the preceding composite layer. In step (d), a cover plate is bonded to the top circuit/insulator composite layer. In step (e), multiple bumps are formed on the bottom circuit/insulator composite layer electrically coupled with the circuit layer of the bottom composite layer.

In an embodiment of this invention, the step (d) is performed before the step (b). That is, the top composite layer is lifted off after being bonded with the cover plate, and the cover plate and the top composite layer together serve as a base in subsequent stacking process, while the top composite layer is the firstly stacked composite layer in the case. In another embodiment, the step (d) is performed after the step (c), and the cover plate is bonded to the last stacked composite layer that turns to be the top composite layer. In the latter case, a preceding cover plate may serve as the base in the stacking process as in the former case, while the preceding cover plate is bonded with the firstly stacked composite layer (bottom composite layer) and is removed after the cover plate is bonded to the last stacked composite layer (top composite layer).

Since the thickness of a circuit/insulator composite layer lifted off from a SOI substrate is much smaller than that of a chip divided from a wafer, the thickness of SIP structure can be significantly reduced in this invention. Moreover, a composite layer is directly stacked onto the preceding composite layer and the bumps are merely formed on the bottom circuit/insulator composite layer, so that conventional carrier substrates as illustrated in FIGS. 1 and 2 can be saved and the number of bumps can be reduced. Therefore, the cost of SIP structure can be reduced. Furthermore, the cover plate serving as a carrier substrate in this invention can be a glass plate that is thinner than a PCB, so that the thickness of SIP structure can be further reduced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates a conventional SIP structure that is usually called stacked CSP.

FIG. 2 illustrates another conventional SIP structure that is Sharp's 3D MCP.

FIGS. 3A(b) and 3B-3H illustrates a process flow of fabricating an SIP structure according to a first embodiment of this invention in a local cross-sectional view, and FIG. 3A(a) illustrates the whole wafer area corresponding to FIG. 3A(b).

FIGS. 4A-4C illustrates a latter part of a process flow of fabricating an SIP structure according to a second embodiment of this invention in a local cross-sectional view, wherein FIG. 4A follows FIG. 3E.

### DESCRIPTION OF THE PREFERRED EMBODIMENTS

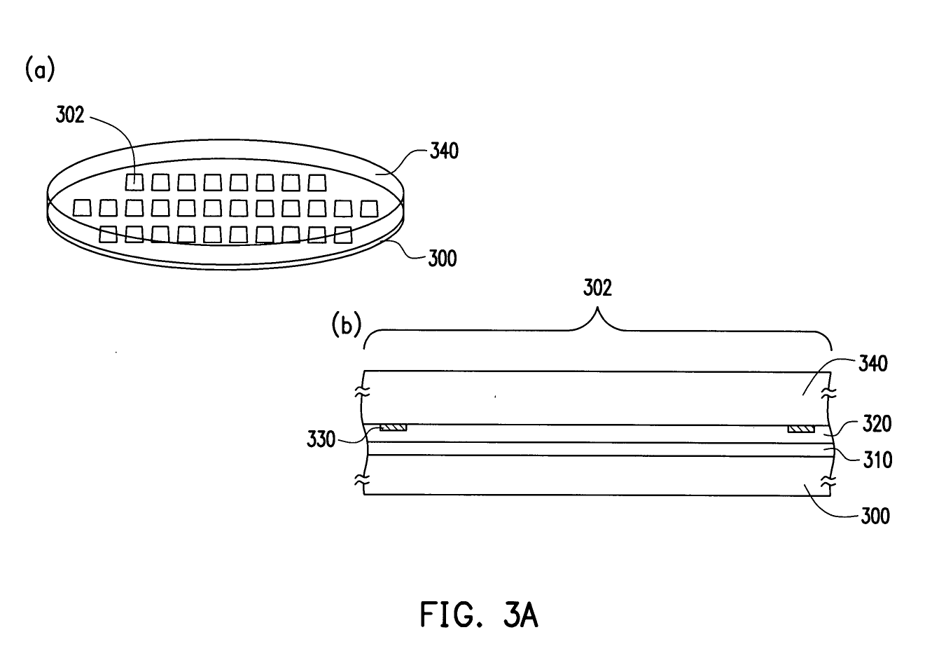

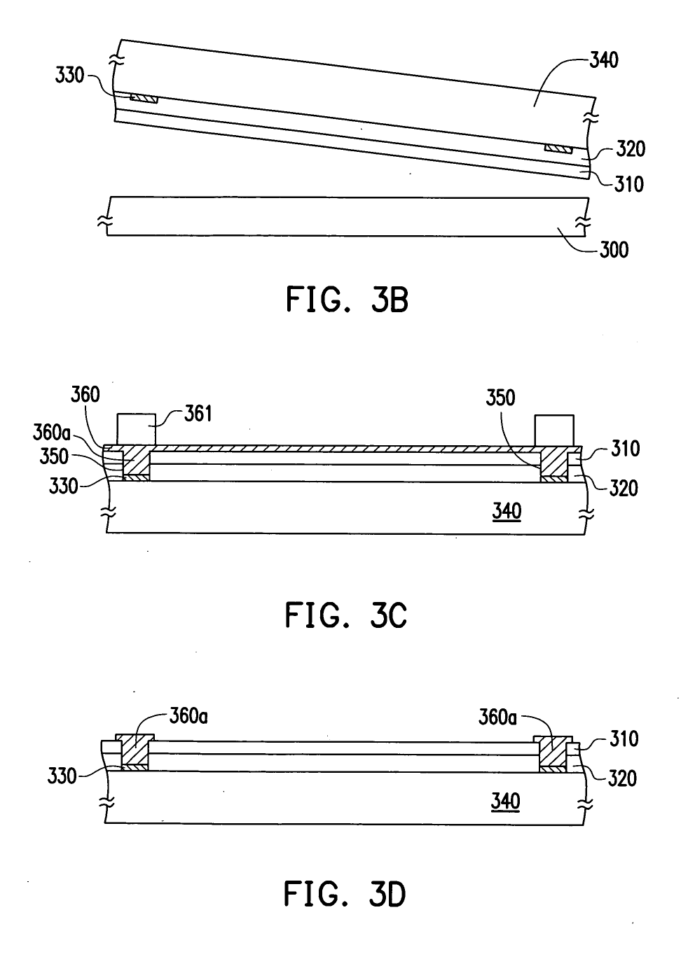

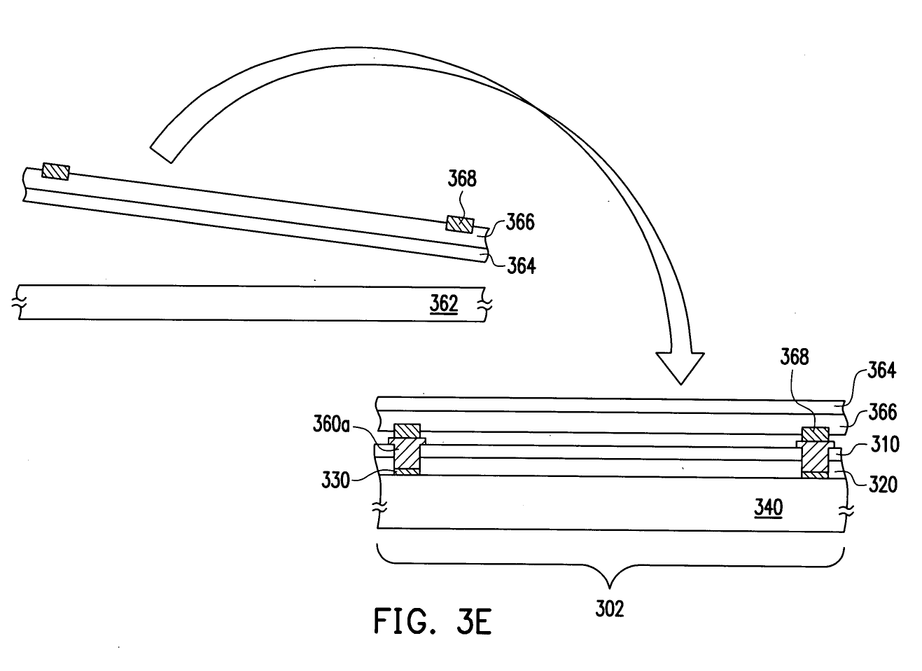

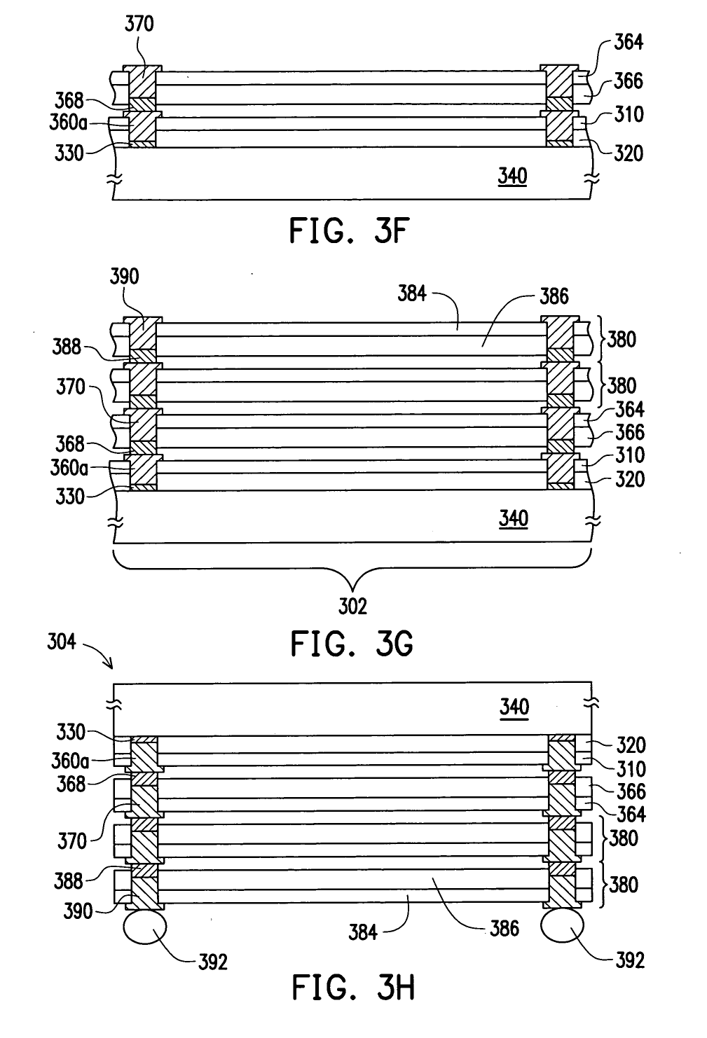

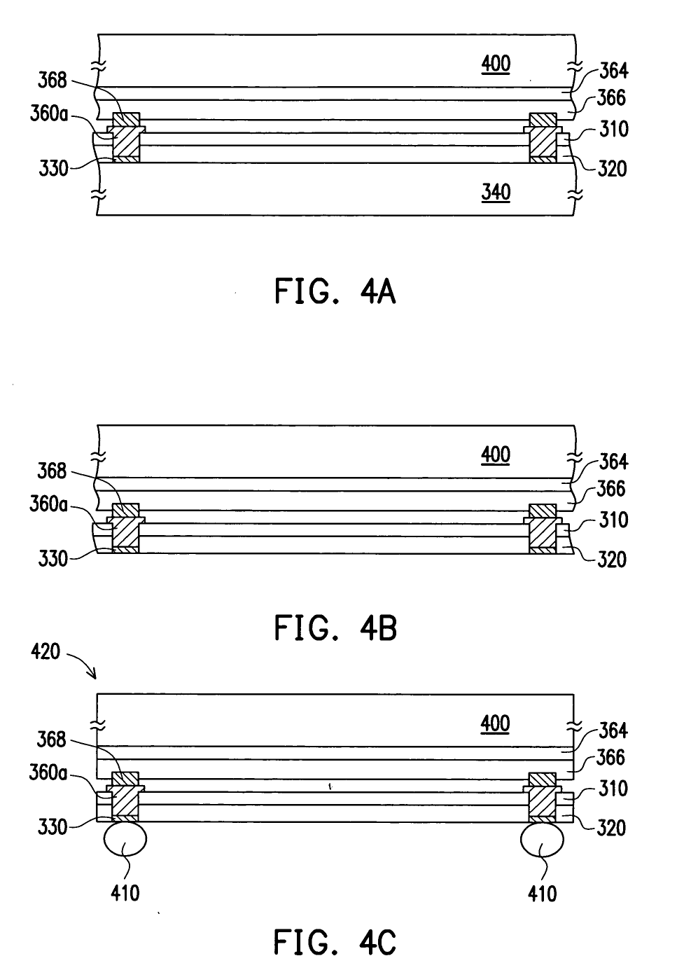

The SIP structures and the corresponding fabricating processes according to the first and second embodiments of this invention are described as follows to further explain this invention, but not to restrict the scope of this invention. For example, the number of the stacked circuit/insulator composite layers is not restricted to 4 or 2 as illustrated in FIG. 3H or 4C, and can be any number larger than one depending on the number of the repeated stacking-step cycles.

### First Embodiment

FIGS. 3A(b) and 3B-3H illustrates a process flow of fabricating an SIP structure according to the first embodiment of this invention in a local cross-sectional view, and FIG. 3A(a) illustrates the whole wafer area corresponding to FIG. 3A(b).

Referring to FIG. 3A(a)/(b), a semiconductor-on-insulator (SOI) wafer 300, such as, a silicon-on-insulator wafer, is provided, including an insulator 310 and a semiconductor layer thereon. The insulator 310 is a buried oxide layer, for example, and the semiconductor layer is a part of the layer 320 described latter. The thickness of the insulator 310 ranges from 1 μm to 10 μm. The SOI wafer 300 is then subjected to a complete fabricating process to form a circuit layer 320 based on the semiconductor layer and to define multiple die regions 302. The thickness of the circuit layer 320 ranges approximately from 10 μm to 100 μm, and the circuit layer 320 within each die region 302 has multiple bonding pads 330 formed thereon. Then, a cover plate 340, such as, a glass plate, is bonded to the circuit layer 320. The thickness of the cover plate ranges approximately from 1 mm to 10 mm, and the cover plate 340 may be bonded to the circuit layer 320 through thermocompression bond.

Referring to FIG. 3B, the circuit layer 320 and the insulator 310 are lifted off from the SOI substrate 300 together with the cover plate 340. The lift-off method can be any suitable method known in the prior art, such as, a hydrogen implantation-annealing method that forms a quasi-continuous gaseous layer between the bulk portion of the SOI substrate 300 and the insulator 310 for their separation.

Referring to FIG. 3C, the composite structure consisting of the three parts 310, 320 and 340 is then flipped, making the insulator face up, to serve as a base for the latter stacking process, while the insulator 310 and the circuit layer 320 together constitute a firstly stacked circuit/insulator composite layer. Then, via holes 350 are formed through the insulator 310 and the circuit layer 320 to the bonding pads 330, and then a conductive material 360 is formed over the insulator 310, filling up the via holes 350 to form plugs 360a.

Referring to FIGS. 3C and 3D, a patterned photoresist layer 361 that defines shoulder portions of the plugs 360a is formed on the conductive material 360. The shoulder portion of a plug 360a is slightly wider than any other portions to ensure the contact between the plug 360a and the corresponding bonding pad of the next stacked circuit/insulator composite layer. The photoresist layer 361 is removed after the conductive material 360 is patterned using the photoresist layer 361 as a mask.

Referring to FIG. 3E, another SOI wafer/substrate 362 formed with an insulator 364 and a circuit layer 366 thereon is provided, wherein the circuit layer 366 is formed with bonding pads 368 thereon. The circuit/insulator composite layer 366/364 is then lifted off from the SOI substrate 362 and stacked on the insulator 310, with the insulator 364 facing up and the die regions thereof aligned with the die regions 302 of the underlying circuit layer 320. The bonding pads 368 on the circuit layer 366 contact with the shoulder portions of the plugs 360a that are electrically connected with the bonding pads 330 on the underlying circuit layer 320, thus electrically connecting to the bonding pads 330.

Referring to FIG. 3F, plugs 370 are formed through the insulator 364 and the circuit layer 366 to connect with the bonding pads 368 with the same steps mentioned above. The shape of each plug 370 can be the same as that of each plug 360a of the preceding circuit/insulator composite layer 320/310.

Referring to FIG. 3G, more circuit/insulator composite layers 380, each of which includes an insulator 384 and a circuit layer 386 formed with bonding pads 388 thereon, are lifted off from other SOI substrates and stacked over the insulator 364 with the same steps mentioned above. It is also required to align the die regions of each circuit/insulator composite layer 380 to the die regions 302 of the base circuit layer 320. After each circuit/insulator composite layer 380 is stacked, plugs 390 are formed through the insulator 384 and the circuit layer 386 to connect with the bonding pads 388 on the circuit layer 386 of the same circuit/insulator composite layer 380.

Referring to FIG. 3H, after the last circuit/insulator composite layer 380 is stacked, bumps 392 are formed on the plugs 390 of the last stacked composite layer 380, wherein the material of the bumps 392 is preferably gold. Thereafter, the resulting stacked structure, which consists of multiple circuit/insulator composite layers from different SOI wafers, the cover plate 340 and the bumps 392, is diced into many single dies 304 defined by the die regions 302 (FIG. 3A(a)).

### Second Embodiment

FIGS. 4A-4C illustrates a latter part of a process flow of fabricating an SIP structure according to the second embodiment of this invention in a local cross-sectional view, while the former part of the process flow may include the same steps as illustrated in FIGS. 3A-3E.

Referring to FIG. 4A, another cover plate 400 is bonded to the insulator 364 of the secondly stacked circuit/insulator composite layer 366/364 (FIG. 3E). The cover plate 400 can be completely the same as the cover plate 340. The material of the cover plate 400 may be glass, and the thickness of the cover plate 400 ranges approximately from 1 mm to 10 mm.

Referring to FIG. 4B, the original cover plate 340 is removed from the circuit layer 320 of the firstly stacked circuit/insulator composite layer 320/310 to expose the bonding pads 330 on the circuit layer 320.

Referring to FIG. 4C, after the cover plate 340 is removed, bumps 410 are formed on the bonding pads 330 of the bottom circuit layer 320, wherein the material of the bumps 392 is preferably gold. Thereafter, the resulting stacked structure, which consists of multiple circuit/insulator composite layers from multiple SOI wafers and the cover plate 400, is diced into many single dies 420 defined by the die regions 302 (FIG. 3A(a)).

Though there are only two circuit/insulator composite layers being stacked in the above description of this embodiment, more composite layers can be stacked onto the insulator 364 with the same steps mentioned above before the cover plate 400 is applied. More specifically, plugs are formed through the insulator and the circuit layer of the preceding composite layer to connect with the bonding pads of the same, and then a new composite layer is stacked onto the preceding one with the circuit layer facing down and the bonding pads thereon electrically connecting with the plugs. However, since the bumps 410 are not formed on the last stacked composite layer 366/364 but on the firstly stacked composite layer 320/310 in this embodiment, no plug is formed through the insulator and the circuit layer of the last stacked composite layer 366/364 to provide electrical connection for the bumps as in the first embodiment.

Moreover, in the above two embodiments of this invention, the circuit layer of each circuit/insulator composite layer may have a memory circuit therein, so that the SIP structure can be obtained as a highly compact memory module.

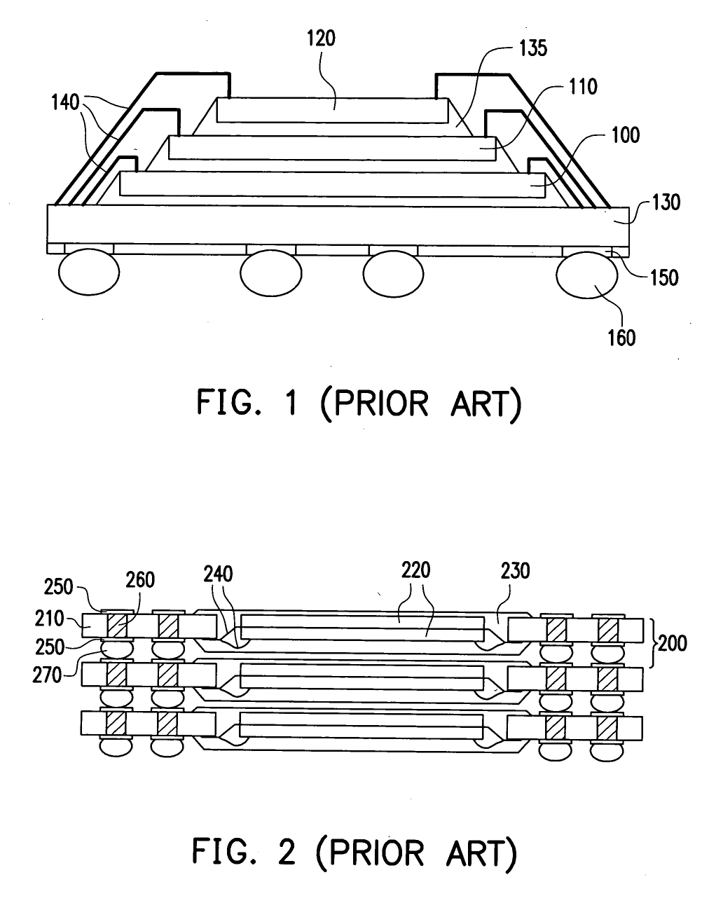

Since the thickness of a circuit/insulator composite layer lifted off from a SOI substrate is much smaller than that of a chip divided from a wafer, the thickness of SIP structure can be significantly reduced in this invention. Moreover, a composite layer is directly stacked onto the preceding composite layer and the bumps are merely formed on the bottom circuit/insulator composite layer, so that conventional carrier substrates as illustrated in FIGS. 1 and 2 can be saved and the number of bumps can be reduced. Therefore, the cost of the SIP structure can be reduced. Furthermore, the cover plate serving as a carrier substrate in this invention can be a glass plate that is thinner than a PCB, so that the thickness of SIP can be further reduced.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

1. A system-in-package (SIP) structure, comprising:
a plurality of stacked circuit/insulator composite layers, including a bottom circuit/insulator composite layer and a top circuit/insulator composite layer, wherein
each circuit/insulator composite layer is lifted off from a semiconductor-on-insulator (SOI) substrate, including the insulator of the SOI substrate and a circuit layer based on the semiconductor of the SOI substrate; and
the circuit layer of a circuit/insulator composite layer is electrically coupled with the circuit layer of an underlying circuit/insulator composite layer;
a plurality of bumps on a lower surface of the bottom circuit/insulator composite layer, electrically connected with the circuit layer of the bottom circuit/insulator composite layer; and
a cover plate on the top circuit/insulator composite layer.

2. The SIP structure of claim 1, wherein the circuit layer of each circuit/insulator composite layer has a plurality of bonding pads thereon, the bonding pads of a circuit/insulator composite layer are electrically connected with the bonding pads of the underlying circuit/insulator composite layer, and the bonding pads of the bottom circuit/insulator composite layer are electrically connected with the bumps.

3. The SIP structure of claim 2, wherein the insulator of each circuit/insulator composite layer faces down, the bumps are disposed on the lower surface of the insulator of the bottom circuit/insulator composite layer, and the cover plate is disposed on the circuit layer of the top circuit/insulator composite layer.

4. The SIP structure of claim 3, wherein the bonding pads of a circuit/insulator composite layer are electrically connected with the bonding pads of the underlying circuit/insulator composite layer via a plurality of plugs through the circuit layer and the insulator of the circuit/insulator composite layer, and the bonding pads of the bottom circuit/insulator composite layer are electrically connected with the bumps via a plurality of plugs through the circuit layer and the insulator of the bottom circuit/insulator composite layer.

5. The SIP structure of claim 2, wherein the circuit layer of each circuit/insulator composite layer faces down, the bumps are disposed on the bonding pads on the circuit layer of the bottom circuit/insulator composite layer, and the cover plate is disposed on the insulator of the top circuit/insulator composite layer.

6. The SIP structure of claim 5, wherein the bonding pads of a circuit/insulator composite layer are electrically connected with the bonding pads of the underlying circuit/insulator composite layer via a plurality of plugs through the insulator and the circuit layer of the underlying circuit/insulator composite layer.

7. The SIP structure of claim 1, wherein the cover plate comprises a glass plate.

8. The SIP structure of claim 1, wherein the SOI substrate is a silicon-on-insulator substrate.

9. The SIP structure of claim 1, wherein the bumps comprise gold bumps.

10. The SIP structure of claim 1, wherein the circuit layer of each circuit/insulator composite layer has a memory circuit therein.

11. A method for fabricating a system-in-package (SIP) structure, comprising:
providing a plurality of semiconductor-on-insulator (SOI) substrates each including an insulator and a circuit layer on the insulator;
lifting off the insulator and the circuit layer from each SOI substrate to obtain a plurality of circuit/insulator composite layers;
vertically stacking the circuit/insulator composite layers, with the circuit layer of a circuit/insulator composite layer coupled with the circuit layer of a preceding circuit/insulator composite layer;
bonding a cover plate to a top circuit/insulator composite layer; and
forming a plurality of bumps on a bottom circuit/insulator composite layer, electrically coupled with the circuit layer of the bottom circuit/insulator composite layer.

12. The method of claim 11, wherein the circuit layer of each circuit/insulator composite layer is formed with a plurality of bonding pads thereon, and the step of stacking a circuit/insulator composite layer on the preceding circuit/insulator composite layer with their circuit layers being coupled comprises:
forming a plurality of plugs through the insulator and the circuit layer of the preceding circuit/insulator composite layer to connect with the bonding pads of the preceding circuit/insulator composite layer; and
stacking the circuit/insulator composite layer on the preceding circuit/insulator composite layer with the bonding pads of the circuit/insulator composite layer contacting with the plugs of the preceding circuit/insulator composite layer.

13. The method of claim 11, wherein the cover plate comprises a glass plate.

14. The method of claim 11, wherein each SOI substrate is a silicon-on-insulator substrate.

15. The method of claim 11, wherein the bumps comprise gold bumps.

16. The method of claim 11, wherein the circuit layer of each circuit/insulator composite layer has a memory circuit therein.

17. A method for fabricating a system-in-package (SIP) structure, comprising:
providing a plurality of semiconductor-on-insulator (SOI) substrates each including an insulator and a circuit layer on the insulator, the insulator and the circuit layer together constituting a circuit/insulator composite layer;
bonding a cover plate to the circuit layer of a first SOI substrate, the insulator and the circuit layer of the first SOI substrate constituting a top circuit/insulator composite layer;
lifting off the top circuit/insulator composite layer from the first SOI substrate together with the cover plate to serve as a base plate;
lifting off the other circuit/insulator composite layers from the other SOI substrates;
sequentially stacking the other circuit/insulator composite layers over the base plate, with the circuit layer of a circuit/insulator composite layer being coupled with the circuit layer of the preceding circuit/insulator composite layer, wherein the last stacked circuit/insulator composite layer is a bottom circuit/insulator composite layer; and
forming a plurality of bumps on the bottom circuit/insulator composite layer, electrically coupled with the circuit layer of the bottom circuit/insulator composite layer.

18. The method of claim 17, wherein each of the other circuit/insulator composite layers is stacked over the base plate with its insulator facing up.

19. The method of claim 18, wherein the circuit layer of each circuit/insulator composite layer is formed with a plurality of bonding pads thereon, and the step of stacking a circuit/insulator composite layer on the preceding circuit/insulator composite layer with their circuit layers being coupled comprises:
forming a plurality of plugs through the insulator and the circuit layer of the preceding circuit/insulator composite layer to connect with the bonding pads of the preceding circuit/insulator composite layer; and
stacking the circuit/insulator composite layer on the preceding circuit/insulator composite layer with the bonding pads of the circuit/insulator composite layer contacting with the plugs of the preceding circuit/insulator composite layer.

20. The method of claim 19, wherein the step of forming the bumps on the bottom circuit/insulator composite layer electrically coupled with the circuit layer of the bottom circuit/insulator composite layer comprises:
forming a plurality of plugs through the insulator and the circuit layer of the bottom circuit/insulator composite layer to connect with the bonding pads of the bottom circuit/insulator composite layer; and
forming the bumps on the plugs of the bottom circuit/insulator composite layer.

21. The method of claim 17, wherein the cover plate comprises a glass plate.

22. The method of claim 17, wherein each SOI substrate is a silicon-on-insulator substrate.

23. The method of claim 17, wherein the bumps comprise gold bumps.

24. A method for fabricating a system-in-package (SIP) structure, comprising:
providing a plurality of semiconductor-on-insulator (SOI) substrates each including an insulator and a circuit layer on the insulator, the insulator and the circuit layer together constituting a circuit/insulator composite layer;
bonding a first cover plate to the circuit layer of a first SOI substrate, the insulator and the circuit layer of the first SOI substrate constituting a bottom circuit/insulator composite layer;
lifting off the bottom circuit/insulator composite layer from the first SOI substrate together with the first cover plate to serve as a base plate;
lifting off the other circuit/insulator composite layers from the other SOI substrates;
sequentially stacking the other circuit/insulator composite layers over the base plate, with the circuit layer of a circuit/insulator composite layer coupled with the circuit layer of the preceding circuit/insulator composite layer, wherein the last stacked circuit/insulator composite layer is a top circuit/insulator composite layer;
bonding a second cover plate to the top circuit/insulator composite layer;
removing the first cover plate from the bottom circuit/insulator composite layer; and
forming a plurality of bumps on the bottom circuit/insulator composite layer, electrically coupled with the circuit layer of the bottom circuit/insulator composite layer.

25. The method of claim 24, wherein each of the other circuit/insulator composite layers is stacked over the base plate with its insulator facing up.

26. The method of claim 25, wherein the circuit layer of each circuit/insulator composite layer is formed with a plurality of bonding pads thereon, and the step of stacking a circuit/insulator composite layer on the preceding circuit/insulator composite layer with their circuit layers being coupled comprises:
forming a plurality of plugs through the insulator and the circuit layer of the preceding circuit/insulator composite layer to connect with the bonding pads of the preceding circuit/insulator composite layer; and
stacking the circuit/insulator composite layer on the preceding circuit/insulator composite layer with the bonding pads of the circuit/insulator composite layer contacting with the plugs of the preceding circuit/insulator composite layer.

27. The method of claim 26, wherein the step of forming the bumps on the bottom circuit/insulator composite layer electrically coupled with the circuit layer of the bottom circuit/insulator composite layer comprises:
forming a plurality of bumps on the bonding pads of the bottom circuit/insulator composite layer after the first cover plate is removed from the bottom circuit/insulator composite layer.

28. The method of claim 24, wherein the cover plate comprises a glass plate.

29. The method of claim 24, wherein each SOI substrate is a silicon-on-insulator substrate.

30. The method of claim 24, wherein the bumps comprise gold bumps.
